(19) United States
(12) Patent Application Publication
(10) Pub. No.: US 2023/0134659 A1
(43) Pub. Date: May 4, 2023

(54) SEMICONDUCTOR DEVICE, THREE-DIMENSIONAL MEMORY AND FABRICATION METHOD OF SEMICONDUCTOR DEVICE

(71) Applicant: YANGTZE MEMORY TECHNOLOGIES CO., LTD., Wuhan (CN)

(72) Inventor: Liang Chen, Wuhan (CN)

(21) Appl. No.: 18/090,357

(22) Filed: Dec. 28, 2022

Related U.S. Application Data
(63) Continuation of application No. PCT/CN2021/127443, filed on Oct. 29, 2021.

(30) Foreign Application Priority Data
Oct. 29, 2020 (CN) 202011186371.5

(51) Int. Cl. H10B 41/23; H10B 41/10; H10B 43/10; H10B 43/23

(52) U.S. Cl. CPC H10B 41/23; H10B 41/10; H10B 43/10; H10B 43/23

(57) ABSTRACT

The present disclosure provides a semiconductor device, a three-dimensional memory and a fabrication method of the semiconductor device. The semiconductor device comprises a substrate, a plurality of gates on a first side of the substrate and extending parallelly in a first horizontal direction, a plurality of first contacts each on a corresponding one of the plurality of gates and extending along the first horizontal direction, and a plurality of second contacts on the first side of the substrate, each second contact extends along the first horizontal direction, and is located between adjacent two first contacts and between two corresponding gates.

### CROSS-REFERENCE TO RELATED APPLICATIONS

This application is a continuation of International Application No. PCT/CN2021/127443, filed on Nov. 11, 2021, which claims the benefit of priority to China Patent Application No. 202011186371.5, filed on Oct. 29, 2020, both of which are incorporated herein by reference in their entireties.

### TECHNICAL FIELD

The present disclosure relates to the technical field of semiconductor memory devices, in particular to a semiconductor device, a three-dimensional (3D) memory, and a fabrication method of the semiconductor device.

### BACKGROUND

A 3D memory is a flash memory device with memory cells that are stacked in a three-dimensional form for a higher storage density per unit area comparing with a planar memory. The existing 3D NAND memory cell architectures are generally in a design of vertical channels and horizontal control gate layers, which can increase the integration level manyfold on a unit area wafer.

In a three-dimensional memory device fabricating process, with the increasing number of array layers, the size of a Complementary Metal Oxide Semiconductor (CMOS) chip has a greater influence on the final size of the entire chip, and there are higher requirements on the miniaturization of CMOS, so there is an increasing need for a capacitor structure with a higher capacitance density.

### SUMMARY

The present disclosure provides a three-dimensional memory and a fabrication method thereof, so as to achieve a high-density capacitor structure of a semiconductor device and a three-dimensional memory device.

The present disclosure provides a semiconductor device which comprises a substrate, a plurality of gates, first contacts corresponding to a plurality of the gates, and a plurality of second contacts; a plurality of the gates are disposed on a surface of the substrate at intervals, with a spacing region between every two adjacent ones of the gates, and sources located in the spacing regions are disposed on the surface of the substrate, each of the gates comprises a connection face, and one of the first contacts is disposed on the connection face of each of the gates, and orthographic projections of the first contacts on the connection faces are strip-shaped, and a length extending direction of the first contacts is the same as a length direction of the gates; a plurality of the second contacts are disposed on the substrate, located in the spacing regions and connected with the sources, and the second contacts and the first contacts are the same in structure and are disposed in juxtaposition.

The present disclosure further provides a three-dimensional memory, comprising the semiconductor device and a memory array, wherein the semiconductor device and the memory array are electrically connected.

The present disclosure further provides a fabrication method of a semiconductor device, and the method comprises: providing a substrate; forming a plurality of gates and sources on the substrate, with a spacing region between every two ones of the gates, each spacing region being provided with one of the sources, wherein the gates comprising connection faces; forming a contact on the connection face of each of the gates and on the substrate within each of the spacing regions, orthographic projections of the contact on the substrate being strip-shaped, and a length extending direction of the contact being the same as a length direction of the gates.

### BRIEF DESCRIPTION OF THE DRAWINGS

For the purpose of illustrating the technical schemes in the implementations of the present disclosure or the prior art more clearly, the figures to be used in the description of implementations or the prior art will be briefly described as follows. Apparently, the figures in the following description are only some of the implementations of the present disclosure. For those of ordinary skill in the art, other figures may be obtained according to these figures without creative work.

FIG. 1 is a schematic structural top view of the semiconductor device provided by the present disclosure.

FIG. 2 is a schematic sectional view of the semiconductor device provided by implementations of the present disclosure.

FIG. 3 is a flowchart of a fabrication method of the semiconductor device provided by the present disclosure.

FIGS. 4-5 are schematic views of various operations of the semiconductor device provided by the present disclosure.

### DETAILED DESCRIPTION

The technical schemes in the implementations of the present disclosure will be described below clearly and completely with reference to the figures in the implementations of the present disclosure. Apparently, the described implementations are merely part of possible implementations of the present disclosure, rather than all implementations. Based on the implementations in the present disclosure, all other implementations obtained by those of ordinary skill in the art without creative work shall fall in the protection scope of the present disclosure.

The existing three-dimensional memory comprises a memory array and a periphery circuit. Memory transistors that are serial in a vertical direction on a lateral substrate are formed in the memory array, and extend in the vertical direction with respect to the substrate. The periphery circuit may be interpreted as a periphery device of the memory, i.e., may be a semiconductor device, which comprises any suitable digital, analog and/or hybrid signal periphery circuit for facilitating memory operation. For example, the periphery device may comprise one or more of a page buffer, a decoder (e.g., a row decoder and a column decoder), a sensing amplifier, a driver, a charge pump, a current or voltage reference, or any active or passive components (e.g., a transistor, a diode, a resistor, or a capacitor) in a circuit. In some fabricating process, the complementary metal oxide semiconductor (CMOS) technology is generally used to form the semiconductor device. An interlayer dielectric (ILD) layer of the semiconductor device formed by such fabrication process can be relatively thin.

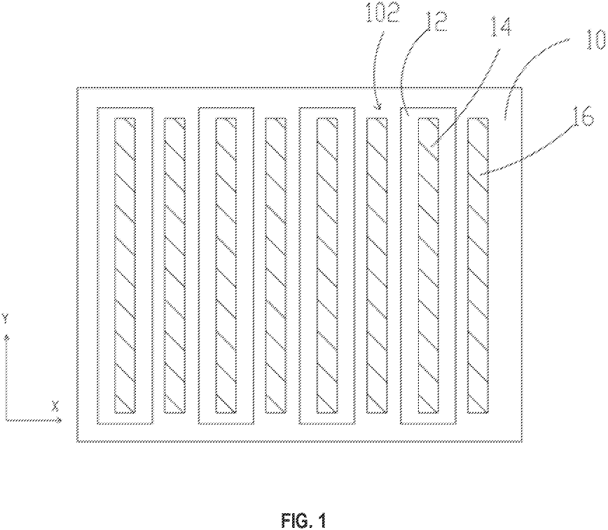

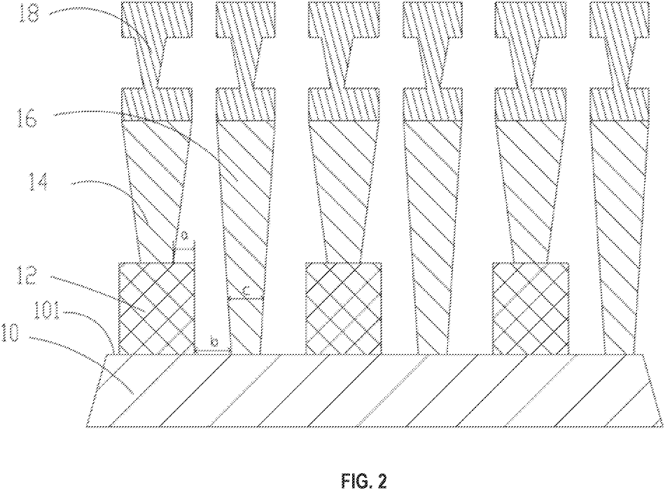

The present disclosure provides a semiconductor device, and a three-dimensional memory comprising the semiconductor device and a memory array, and the semiconductor device is electrically connected with the memory array. Referring to FIGS. 1 and 2, the semiconductor device in the implementations of the present disclosure comprises a substrate 10, a plurality of gates 12, first contacts 14 corresponding to a plurality of the gates 12, and a plurality of second contacts 16.

A plurality of the gates 12 are disposed on a surface 101 of the substrate 10 at intervals, with a spacing region 102 between every two adjacent ones of the gates 12, and sources (not shown) located in the spacing regions 102 are disposed on the surface 101 of the substrate 10.

Each of the gates 12 comprises a connection face 121, and one of the first contacts 14 is disposed on the connection face 121 of each of the gates 12, and orthographic projections of the first contacts 14 on the connection faces 121 are strip-shaped, and a length extending direction of the first contacts 14 is the same as a length direction of the gates 12.

A plurality of second contacts 16 are disposed on the substrate 10, located in the spacing regions 102 and connected with the sources (not shown). The second contacts 16 and the first contacts 14 can have similar structures and can be arranged in parallel.

As shown in FIG. 2, particularly, the semiconductor device is a periphery circuit that provides electrical connection to the three-dimensional memory; each gate 12 is led out through one first contact 14 to achieve electrical connection; and each source is connected with one of the second contacts 16. An ILD layer (not shown) is formed on the substrate 10 and covers surfaces of the gates 12 and the substrate 10, and the first contacts 14 and the second contacts 16 are formed within the ILD layer. In a width direction of the gates 12, an orthographic projection of each of the first contacts 14 and the second contacts 16 is rectangular, that is, the first contacts 14 and the second contacts 16 are in a rectangular plate body shape as viewed perpendicular to a length direction of the gates. The ILD layer is thinner in thickness to better facilitate formation of the first contacts 14 and the second contacts 16 in a plate shape form. In the same unit area, the first contacts 14 and the second contacts 16 are in a plate shape, rather than in a dot matrix form, to make the area of the first contacts 14 and the second contacts 16 increase, so that the capacitance provided by them within the semiconductor device is increased.

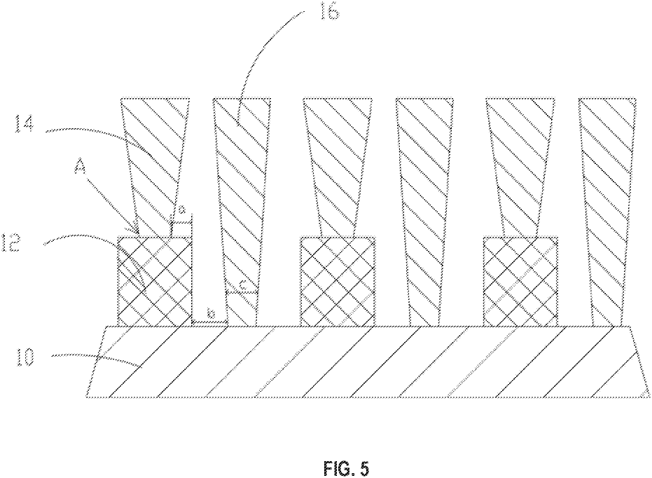

Further, as shown in FIG. 5, cross sections of the first contacts 14 in the width direction of the gates 12 are trapezoids, and the top sides A of the trapezoids are connected with the connection faces of the gates 12. Particularly, with reference to FIG. 1, the width direction of the gates 12 is interpreted as an X direction; the length direction of the gates 12 is a Y direction; a plurality of the gates 12 are arranged at intervals in the X direction; and a plurality of the first contacts 14 are arranged at intervals in the X direction. As viewed in the X direction, the first contacts 14 present as rectangular plate bodies; while as viewed in the Y direction, the sections of the first contacts 14 are trapezoids, and the shorter top sides of the trapezoids are connected with the connection faces of the gates 12. On the premise of ensuring connection performance, the contact area of the first contacts 14 with the gates 12 are ensured in the X direction, that is, the surface contact area of the first contacts 14 with the gates 12 is large enough. To ensure that the distance between the first contacts 14 and the second contacts 16 is decreased, the distance α between the first contacts 14 and the surface edges of the gates 12 is above about 50 to 70 nanometers, which ensures that the first contacts can contact with the surfaces of the gates accurately, and can also ensure that the distance between two contacts is decreased.

Further, the distance b between the second contacts 16 within the spacing regions 102 and the two gates 12 forming the spacing regions is about 50 to 70 nanometers, which can decrease the distance between every two contacts (the first contacts 14 and the second contacts 16) and increase the capacitance. The structure of the second contacts 16 can be the same as that of the first contacts 14. As viewed in the X direction, the second contacts 16 present as rectangular plate bodies; while as viewed in the Y direction, the sections of the second contacts 16 are trapezoids, and shorter top sides of the trapezoids are connected with the sources on the substrate 10. The dimension c at the end of the second contacts 16 connecting with the sources on the substrate 10 are decreased in the X direction, thereby reducing the gate density, increasing the number of the second contacts per unit area, and further increasing the capacitance.

In the present disclosure, the first contacts 14 and the second contacts 16 present as rectangular plate bodies. Compared with the disposition form of multiple contacts, the area of the contacts is increased, thereby increasing the capacitance.

Further, the semiconductor device further comprises metal layers 18 that are formed on the surfaces of a plurality of the first contacts and a plurality of second contacts far away from the substrate and are used to electrically connect the first contacts 14 and the second contacts 16 with other devices of the memory. Particularly, the metal layers 18 comprise first metal layers and second metal layers that are stacked and spaced by insulating layers, and the first metal layers are connected with the second metal layers by through-holes.

A fabrication method of a semiconductor device provided by the present disclosure is introduced below in detail with reference to the foregoing semiconductor device. In other implementations, a semiconductor device obtained by the fabrication method of the semiconductor device may also be different from the semiconductor device of the foregoing implementations.

The present disclosure provides a fabrication method of a semiconductor device, which is characterized by comprising:

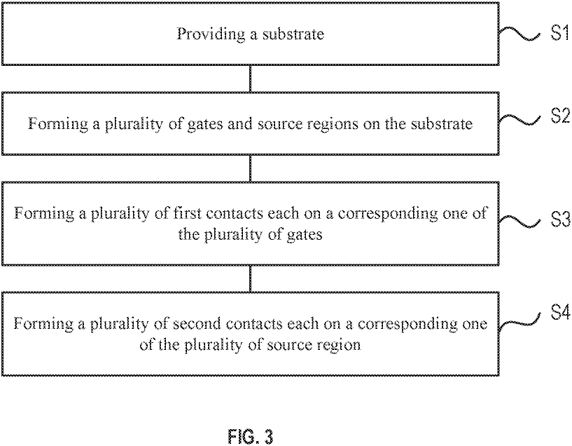

Referring to FIG. 3, at operation S1, a substrate 10 is provided for supporting a device structure thereon. In this implementation, the material of the substrate 10 is monocrystalline silicon (Si). Of course, in other implementations, the material of the substrate 10 may be an element semiconductor, such as germanium (Ge); a compound semiconductor, such as silicon germanium (SiGe), silicon carbide (SiC), gallium arsenide (GaAs), gallium phosphide (GaP), indium phosphide (InP), indium arsenide (InAs) and/or indium antimonide (InSb); an alloy semiconductor, such as gallium arsenic phosphide (GaAsP), aluminum indium arsenide (AlInAs), aluminum gallium arsenide (AlGaAs), gallium indium arsenide (GaInAs), gallium indium phosphide (GaInP) and/or gallium indium arsenic phosphide (GaInAsP); or a combination thereof. Furthermore, the substrate 10 may be a “semiconductor on insulator” wafer.

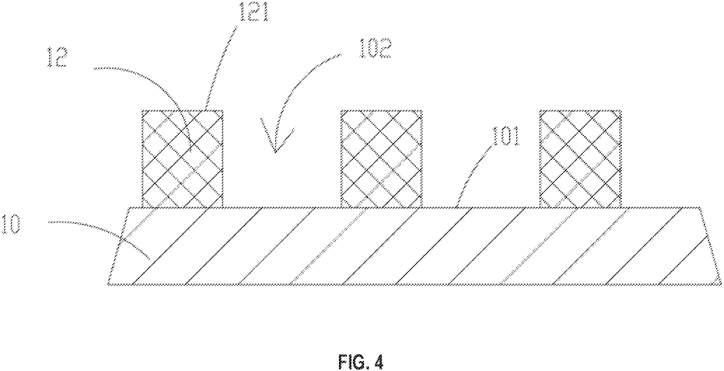

Referring to FIG. 4, at operation S2, a plurality of gates 12 and sources (not shown) are formed on the substrate 10, with a spacing region 102 between every two ones of the gates 12, and each spacing region 102 being provided with one of the sources, wherein the gates 12 comprise connection faces 121. The material of the gates 12 may be silicon nitride (SixNy, e.g., SiN), amorphous silicon, polysilicon, aluminum oxide, or a combination thereof. The gates 12 may be formed by means of coating and etching or photomasking. Specifically, gate sacrificial layers are formed first, and will be replaced with metals to serve as the gates in a subsequent process.

Further, the operation of forming a plurality of the gates 12 and the sources on the substrate 10 further comprises forming an ILD layer (not shown) that covers the gates 12 and the sources on the substrate 10.

Referring to FIG. 5, at operation S3, a first contact 14 is formed on the connection face 121 of each of the gates 12 through masking and etching processes, and orthographic projections of the first contacts 14 on the connection faces 121 are strip-shaped, and a length extending direction of the first contacts 14 is the same as a length direction of the gates 12. Also, the orthographic projections of the first contacts 14 on the connection faces 121 are within the orthographic projections of the gates 12. The first contacts 14 may be made from W, Ru, Co, or other suitable conductive materials. The first contacts 14 may be formed by filling through-holes formed in the ILD layer. Specifically, the through-holes may be formed in the ILD layer by a mask in conjunction with an etching method, which will not be described in detail.

This implementation further comprises operation IV: forming a second contact 16 on the substrate 10 within each of the spacing regions 102 by masking and etching processes to make the second contacts 16 connect with the sources, wherein the second contacts 16 and the first contacts 14 are the same in structure and are disposed in juxtaposition. The second contacts 16 may be made from W, Ru, Co, or other suitable conductive materials. The second contacts 16 may be formed by filling through-holes formed in the ILD layer. Specifically, the through-holes may be formed in the ILD layer by a mask in conjunction with an etching method, which will not be described in detail.

It should be noted that, when forming the first contacts 14, cross sections of the first contacts 14 in a width direction of the gates 12 are trapezoids, and top sides of the trapezoids are connected with the gates 12; and in the width direction of the gates 12, the orthographic projection of each of the first contacts 14 and the second contacts 16 is rectangular. In other implementations, the first contacts 14 and the second contacts 15 are formed simultaneously.

The fabrication method of the semiconductor device further comprises forming metal layers 18 that are formed on surfaces of a plurality of the first contacts 14 and a plurality of second contacts 16 far away from the substrate 10 and on the ILD layer, and drains corresponding to the sources are disposed on the metal layers 18. The metal layers may be made from Cu, Al, Ru, Co, W, or other suitable conductive materials.

In the semiconductor device provided by the present disclosure, the orthographic projections of the first contacts on the connection faces of the gates are strip-shaped, and the length extending direction of the first contacts is the same as the length direction of the gates; the second contacts and the first contacts are the same in structure, and the individuals of the first contacts and the second contacts are embodied in a non-dot matrix form, so that the unit area of the contacts is increased, and the capacitance may be increased, for achieving a high density capacitor structure of the semiconductor device and the three-dimensional memory device.

The implementations of the present disclosure disclosed above should not limit the scope of the claims of the present disclosure. Those of ordinary skill in the art may understand that implementation of all or part of processes of the above implementations, and equivalent variations made according to the claims of the present disclosure still fall in the scope encompassed by the present disclosure.

1. A semiconductor device, comprising:
a substrate;
a plurality of gates on a first side of the substrate and extending parallelly in a first horizontal direction;
a plurality of first contacts each on a corresponding one of the plurality of gates and extending along the first horizontal direction; and
a plurality of second contacts on the first side of the substrate, each second contact extends along the first horizontal direction, and is located between adjacent two first contacts and between two corresponding gates.

2. The semiconductor device of claim 1, wherein:
each second contact is in contact with a source region exposed on the first side the substrate between two adjacent gates; and
the substrate further comprises a plurality of drain regions exposed on a second side of the substrate opposite to the first side.

3. The semiconductor device of claim 1, wherein the plurality of gates are equally separated from each other at an interval in a second horizontal direction.

4. The semiconductor device of claim 3, wherein:
a projection of each first contact on the corresponding gate has a strip shape; and
a projection of each second contact on the substrate has the strip shape.

5. The semiconductor device of claim 4, wherein:
a first length of each first contact in the first horizontal direction is equal to a second length of each second contact in the first horizontal direction; and
a first width of each first contact in the second horizontal direction is equal to a second width of each second contact in the second horizontal direction.

6. The semiconductor device of claim 5, wherein:
a first height of each first contact in a vertical direction is less than a second height of each second contact in the vertical direction; and
top surfaces of the plurality of first contacts are coplanar with top surfaces of the plurality of second contacts.

7. The semiconductor device of claim 5, wherein:
a cross section of each first contact in the second horizontal direction and the vertical direction is a trapezoid shape with a short base of the trapezoid shape in contact with the corresponding one of the plurality of gates; and
a cross section of each first contact in the first horizontal direction and the vertical direction is a rectangle shape.

8. The semiconductor device of claim 5, wherein:
a cross section of each second contact in the second horizontal direction and the vertical direction is a trapezoid shape with a short base of the trapezoid shape in contact with the substrate; and
a cross section of each second contact in the first horizontal direction and the vertical direction is a rectangle shape.

9. The semiconductor device of claim 1, wherein:
a first distance between an edge of each first contact and an edge of its corresponding gate is in a range from about 50 nanometers to about 70 nanometers; and
a second distance between each second contact and its adjacent gate is in a range from about 50 nanometers to about 70 nanometers.

10. The semiconductor device of claims 1, further comprising at least one metal layer on the plurality of the first contacts and the plurality of the second contacts.

11. The semiconductor device of claim 1, further comprising an interlayer dielectric layer covering the substrate and the plurality of gates, wherein the plurality of first contacts and the plurality of second contacts are embedded within the interlayer dielectric layer.

12. A three-dimensional memory device, comprising:
a three-dimensional memory array; and
a semiconductor device electrically connected with the three-dimensional memory array, the semiconductor device comprising:
a substrate,
a plurality of gates on a first side of the substrate and extending parallelly in a first horizontal direction,
a plurality of first contacts each on a corresponding one of the plurality of gates and extending along the first horizontal direction, and
a plurality of second contacts on the first side of the substrate, each second contact extends along the first horizontal direction, and is located between adjacent two first contacts and between two corresponding gates.

13. A method of fabricating a semiconductor device, comprising:
providing a substrate comprising a plurality of source regions on a first side of the substrate and a plurality of drain regions on a second side of the substrate opposite to the first side;
forming a plurality of gates on the first side of the substrate between the plurality of source regions and extending parallelly in a first horizontal direction;
forming a plurality of first contacts each on a corresponding one of the plurality of gates and extending along the first horizontal direction; and
forming a plurality of second contacts on the first side of the substrate, each second contact extends along the first horizontal direction, and is located between adjacent two first contacts and between two corresponding gates, and in contact with a source region.

14. The method of claims 13, further comprising:
forming at least one metal layer on the plurality of the first contacts and the plurality of the second contacts.

15. The method of claim 13, further comprising:
forming an interlayer dielectric layer covering the substrate and the plurality of gates, wherein the plurality of first contacts and the plurality of second contacts are formed to penetrate the interlayer dielectric layer.

16. The method of claim 13, wherein:
the plurality of gates are formed equally separated from each other at an interval in a second horizontal direction.

17. The method of claim 13, wherein:
the plurality of first contacts and the plurality of second contacts are formed in a same patterning process.

18. The method of claim 13, further comprising:
performing a chemical mechanical polishing process to planarize top surfaces of the plurality of first contacts and the plurality of second contacts.

19. The method of claim 13, wherein:
the plurality of first contacts and the plurality of second contacts are formed to have a same length in the first horizontal.

20. The method of claim 13, wherein:
forming the plurality of first contacts comprises arranging a first distance between an edge of each first contact and an edge of its corresponding gate in a range from about 50 nanometers to about 70 nanometers; and
forming the plurality of second contacts comprises arranging a second distance between each second contact and its adjacent gate is in a range from about 50 nanometers to about 70 nanometers.
